(19) United States
(12) Patent Application Publication
(10) Pub. No.: US 2004/0110084 A1
(43) Pub. Date: Jun. 10, 2004

(54) Photosensitive insulating resin composition and cured product thereof

(75) Inventors: Katsumi Inomata, Tokyo (JP); Atsushi Ito, Tokyo (JP); Masako Suzuki, Tokyo (JP); Shin-ichiro Iwanaga, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: JSR CORPORATION, Tokyo (JP)

(21) Appl. No.: 10/314,209

(22) Filed: Dec. 9, 2002

(51) Int. Cl. G03F 7/038

(52) U.S. Cl. 430/270.1; 430/138; 430/910; 430/905

(57) ABSTRACT

Disclosed is a photosensitive insulating resin composition comprising (A) an alkali-soluble resin having a phenolic hydroxyl group, (B) a compound containing at least two alkyl-etherificated amino groups in the molecule, (C) crosslinked fine particles, (D) a photosensitive acid generator and (E) an organic solvent. Also disclosed is a cured product obtained by curing the photosensitive insulating resin composition. From the photosensitive insulating resin composition, a cured product excellent not only in resolution, electrical insulation properties and thermal shock resistance but also in heat resistance and chemical resistance can be obtained.

### FIELD OF THE INVENTION

The present invention relates to a photosensitive insulating resin composition employable for printed circuit boards or the like and a cured product obtained by curing the composition. More particularly, the invention relates to a cured product that is excellent not only in resolution but also in other properties such as electrical insulating properties, thermal shock resistance, heat resistance and chemical resistance, and a solder resist-forming photosensitive insulating resin composition from which the above-mentioned cured product can be obtained.

### BACKGROUND OF THE INVENTION

In the field of production of printed circuit boards, solder resists are used for the purpose of preventing sticking of solder to the unnecessary portions during the soldering process or making an opening in a conductor pad on which an IC chip is to be mounted and protecting other conductor circuits.

With the recent tendency toward lightweight, thin and small-sized electronic equipments, solder resists have been required to be excellent in various properties such as adhesion, electrical insulating properties, soldering heat resistance, solvent resistance, impact resistance and resolution in order to cope with the production of high-density printed circuit boards or the surface mounting of parts.

As solder resists, those of thermosetting epoxy type have been heretofore employed, but they have problems in chemical resistance, soldering heat resistance, etc. For the purpose of improving workability and productivity, a number of ultraviolet curing type solder resists have been employed. For example, Japanese Patent Laid-Open Publication No. 180501/1994 discloses a solder resist composition comprising a reaction product of an ester compound of a polyfunctional epoxy resin and an unsaturated monocarboxylic acid with a polybasic anhydride, a guanamine resin (see the following formula (1)) obtained by adding formaldehyde to a part or all of amino groups and alkyl-etherificated a part or all of the resulting addition product with an alcohol of 4 or less carbon atoms, and a photopolymerization initiator. This composition, however, is not satisfactory in the properties necessary for high-density printed circuit boards.

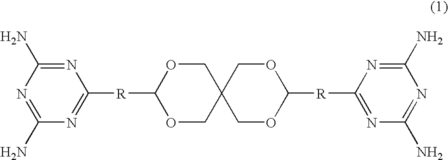

In the formula (1), R is a divalent hydrocarbon group of 2 to 8 carbon atoms.

In Japanese Patent Laid-Open Publication No. 316173/1997, a resin composition comprising an epoxy resin, an allyl nadimide compound and a cationic photopolymerization initiator is disclosed. The resin composition described in Japanese Patent Laid-Open Publication No. 316173/1997 has excellent heat resistance, adhesion and chemical resistance, but the impact resistance and the resolution of the composition have not been studied sufficiently and are not necessarily satisfactory.

In Japanese Patent Laid-Open Publication No. 7886/2000, there is disclosed a solder resist composition containing as main components an acrylate of a novolak epoxy resin and a thermoplastic resin and exhibiting excellent crack resistance under the heat cycle conditions. In this publication, however, properties such as resolution are not described.

For producing a printed wiring board, a subtractive process wherein the unnecessary portion of a copper foil of a copper-clad laminate is removed by etching to form a circuit has been heretofore employed. According to this process, however, it is difficult to precisely form wiring of a fine pattern corresponding to a high-density printed wiring board. On this account, a fully additive process wherein a circuit is formed by electroless plating is paid attention. The insulating material suitable for this process needs to not only have excellent resolution but also exhibit electrical insulating properties, soldering heat resistance, chemical resistance and thermal reliability in the laminating. In Japanese Patent Laid-Open Publication No. 60895/1999, there is disclosed a permanent resist resin composition which comprises a phenolic resin, an ethylenically unsaturated group-containing compound, a photopolymerization initiator and a compound having a carbodiimide group and has excellent soldering heat resistance and solvent resistance. In this publication, however, the thermal shock resistance and the resolution of the composition are not described at all.

Accordingly, development of a photosensitive insulating resin composition that is excellent also in the resolution and the heat resistance has been desired.

### OBJECT OF THE INVENTION

The present invention is intended to solve such problems associated with the prior art as described above, and it is an object of the invention to provide a photosensitive insulating resin composition from which a cured product excellent in various properties, such as resolution, electrical insulating properties, thermal shock resistance and chemical resistance, can be obtained and which is favorable as a solder resist and suitable for forming fine wiring.

It is another object of the invention to provide a cured product obtained by curing the photosensitive insulating resin composition.

### SUMMARY OF THE INVENTION

The present inventors have earnestly studied in order to solve the above problems, and as a result, they have found that a photosensitive insulating resin composition comprising specific components has excellent properties. Based on the finding, the present invention has been accomplished.

That is to say, the photosensitive insulating resin composition of the invention comprises (A) an alkali-soluble resin having a phenolic hydroxyl group, (B) a compound containing at least two alkyl-etherificated amino groups in the molecule, (C) crosslinked fine particles, (D) a photosensitive acid generator and (E) a solvent.

In the photosensitive insulating resin composition, the compound (B), the crosslinked fine particles (C) and the photosensitive acid generator (D) are preferably contained in amounts of 1 to 100 parts by weight, 1 to 50 parts by weight and 0.1 to 10 parts by weight, respectively, based on 100 parts by weight of the alkali-soluble resin (A).

### BRIEF DESCRIPTION OF THE DRAWINGS

FIG. 1 is a schematic view of a section of a board prepared in each of the examples and the comparative examples.

FIG. 2 is a schematic view of a surface of a board prepared in each of the examples and the comparative examples.

1: board

2: substrate

3: copper foil

### DETAILED DESCRIPTION OF THE INVENTION

The photosensitive insulating resin composition and its cured product are described in detail hereinafter.

### Photosensitive insulating resin composition

The photosensitive insulating resin composition of the invention comprises (A) an alkali-soluble resin having a phenolic hydroxyl group, (B) a compound containing at least two alkyl-etherificated amino groups in the molecule, (C) crosslinked fine particles, (D) a photosensitive acid generator and (E) a solvent. In the photosensitive insulating resin composition of the invention, additives, such as an epoxy resin, an inorganic filler, a colorant, a sensitizer and a leveling agent, may be contained when needed.

### (A) Alkali-soluble resin having phenolic hydroxyl group

The alkali-soluble resin having a phenolic hydroxyl group (referred to as a “phenolic resin (A)” hereinafter) for use in the invention is not specifically restricted, and examples thereof include phenol-formaldehyde condensation novolak resin, cresol-formaldehyde condensation novolak resin, phenol-naphthol-formaldehyde condensation novolak resin, polyhydroxystyrene and its copolymers, phenol-xylylene glycol condensation resin, cresol-xylylene glycol condensation resin, and phenol-dicyclopentadiene condensation resin. These phenolic resins may be used as a mixture of two or more kinds.

In combination with the alkali-soluble resin having a phenolic hydroxyl group, a phenolic low-molecular weight compound (referred to as a “phenolic compound (a)” hereinafter) can be employed. Examples of such compounds include 4,4′-dihydroxydiphenylmethane, 4,4′-dihydroxydiphenyl ether, tris(4-hydroxyphenyl)methane, 1,1-bis(4-hydroxyphenyl)-1-phenylethane, tris(4-hydroxyphenyl)ethane, 1,3-bis[1-(4-hydroxyphenyl)-1-methylethyl]benzene, 1,4-bis[1-(4-hydroxyphenyl)-1-methylethyl]benzene, 4,6-bis[1-(4-hydroxyphenyl)-1-methylethyl]-1,3-dihydroxybenzene, 1,1-bis(4-hydroxyphenyl)-1-[4-{1-(4-hydroxyphenyl)-1-methylethyl}phenyl]ethane and 1,1,2,2-tetra(4-hydroxyphenyl)ethane.

In the alkali-soluble resin (A) having a phenolic hydroxyl group, the phenolic low-molecular weight compound (a) has only to be contained as a part of the component (A), in an amount of 0 to 40% by weight, particularly 0 to 30% by weight.

From the viewpoints of resolution, developing properties and plating solution resistance of the resulting insulating layer, the phenolic compound (A) needs to have a weight-average molecular weight of not less than 2000 and preferably has a weight-average molecular weight of 2000 to 20000.

The amount of the phenolic resin (A) (total amount of the phenolic resin (A) and the phenolic compound (a) when the components (A) and (a) are used in combination) contained in the composition of the invention has only to be such an amount that the resulting insulating layer exhibits sufficient alkali solubility, and is in the range of usually 30 to 75% by weight, preferably 40 to 70% by weight, based on the whole composition. When the amount of the phenolic resin is in this range, an insulating thin film formed from the resulting composition exhibits satisfactory developing properties with an alkaline aqueous solution, and besides an insulating layer obtained by further curing the composition exhibits excellent heat resistance and plating solution resistance.

### (B) Compound containing at least two alkyl-etherificated amino groups in molecule

The compound having at least two alkyl-etherificated amino groups in the molecule (referred to as a “crosslinking agent (B)” hereinafter) functions as a crosslinking component which reacts with the phenolic resin (A). The alkyl-etherificated amino group present in the molecule is represented by, for example, the following formula:

—NHR¹—O—R²

wherein R¹ is an alkylene group (divalent hydrocarbon group), and R² is an alkyl group.

The crosslinking agent (B) is, for example, a compound wherein all or a part (at least two) of active methylol groups (CH₂OH groups) in a nitrogen compound such as (poly)methylolated melamine, (poly)methylolated glycoluril, (poly)methylolated benzoguanamine or (poly)methylolatd urea are alkyl-etherificated. Examples of alkyl groups to constitute the alkyl ethers include methyl, ethyl and butyl. The alkyl groups to constitute two or more of the alkyl ethers contained in the crosslinking agent (B) may be the same as or different from each other. If the crosslinking agent (B) contains methylol groups having been not alkyl-etherificated, the methylol groups may be self-condensed with each other, or the methylol groups of two or more compounds may be condensed with each other to form an oligomer component.

Examples of the crosslinking agents (B) employable in the invention include hexamethoxymethylated melamine, hexabutoxymethylated melamine, tetramethoxymethylated glycoluril and tetrabutoxymethylated glycoluril. These crosslinking agents (B) may be used singly or in combination of two or more kinds.

The amount of the crosslinking agent (B) in the invention is in the range of 1 to 100 parts by weight, preferably 5 to 50 parts by weight, based on 100 parts by weight of the phenolic resin (A) (100 parts by weight of the total of the phenolic resin (A) and the phenolic compound (a) when the components (A) and (a) are used in combination; the same shall apply with regard to the later-described components (C) to (E)). If the amount of the crosslinking agent (B) is less than 1 part by weight, curing due to the exposure becomes insufficient, and as a result, patterning may become difficult or heat resistance of the resulting cured product may be lowered. If the amount exceeds 100 parts by weight, lowering of resolution or lowering of electrical insulating properties occasionally takes place.

### (C) Crosslinked fine particles

The crosslinked fine particles (C) for use in the invention are those having Tg of not higher than 0° C. Such crosslinked fine particles (C) are present in the composition of the invention in the homogeneously dispersed state. These fine particles function as cushioning materials against thermal shock and exert excellent properties.

There is no specific limitation on the crosslinked fine particles (C) provided that they have Tg of the above range and are compatible with other components to a certain extent. In the present invention, however, preferably used are crosslinked fine particles obtained by copolymerizing a crosslinking monomer having two or more unsaturated polymerizable groups (referred to as a “crosslinking monomer” hereinafter) and one or more other monomers selected so that Tg of the resulting crosslinked fine particles (C) becomes not higher than 0° C. (referred to as “other monomers” hereinafter), and particularly preferably used are crosslinked fine particles obtained by copolymerizing the crosslinking monomer and other monomers having a functional group other than the polymerizable group, such as a carboxyl group, an amino group or a hydroxyl group.

Examples of the crosslinking monomers include compounds having plural polymerizable unsaturated groups, such as divinylbenzene, diallyl phthalate, ethylene glycol di(meth)acrylate, propylene glycol di(meth)acrylate, trimethylolpropane tri(meth)acryalte, pentaerythritol tri(meth)acrylate, polyethylene glycol di(meth)acrylate and polypropylene glycol di(meth)acrylate.

Examples of the other monomers include:

unsaturated nitrile compounds, such as butadiene, isoprene, dimethylbutadiene, chloroprene, 1,3-pentadiene, (meth)acrylonitrile, α-chloroacrylonitrile, α-chloromethylacrylonitrile, α-methoxyacrylonitrile, α-ethoxyacrylonitrile, crotononitrile, cinnamoyl nitrile, itaconic acid dinitrile, maleic acid dinitrile and fumaric acid dinitrile;

unsaturated amides, e.g., amido group-containing unsaturated compounds, such as (meth)acrylamide, N,N′-methylenebis(meth)acrylamide, N,N′-ethylenebis(meth)acrylamide, N,N′-hexamethylenebis(meth)acrylamide, N-hydroxymethyl(meth)acrylamide, N-(2-hydroxyethyl)(meth)acrylamide, N,N-bis(2-hydroxyethyl)(meth)acrylamide, crotonamide, cinnamamide and dimethyl(meth)acrylamide;

(meth)acrylic acid esters, such as methyl (meth)acrylate, ethyl (meth)acrylate, propyl (meth)acrylate, butyl (meth)acrylate, hexyl (meth)acrylate, lauryl (meth)acrylate, polyethylene glycol (meth)acrylate and polypropylene glycol (meth)acrylate;

aromatic vinyl compounds, such as styrene, α-methylstyrene, o-methoxystyrene, p-hydroxystyrene and p-isopropenylphenol;

epoxy group-containing unsaturated compounds, such as glycidyl (meth)acrylate and (meth)allyl glycidyl ether;

hydroxyl group-containing unsaturated compounds, such as hydroxyethyl (meth)acrylate, hydroxypropyl (meth)acrylate and hydroxybutyl (meth)acrylate;

unsaturated acid compounds, such as (meth)acrylic acid, itaconic acid, β-(meth)acryloxyethyl succinate, β-(meth)acryloxyethyl maleate, β-(meth)acryloxyethyl phthalate and β-(meth)acryloxyethyl hexahydrophthalate; and

amino group-containing unsaturated compounds, such as dimethylamino(meth)acrylate and diethylamino(meth)acrylate.

Of the above-mentioned other monomers, preferably used are butadiene, isoprene, (meth)acrylonitrile, (meth)acrylic acid alkyl esters, styrene, p-hydroxystyrene, p-isopropenylphenol, glycidyl (meth)acrylate, (meth)acrylic acid and hydroxyalkyl (meth)acrylates.

The crosslinked fine particles (C) for use in the invention are preferably those obtained by copolymerizing the crosslinking monomer and the other monomers in such amounts that the proportion of the crosslinking monomer to the total of the crosslinking monomer and the other monomers is in the range of preferably 1 to 20% by weight, more preferably 2 to 10% by weight.

The process for preparing the crosslinked fine particles (C) is described below in detail.

There is no specific limitation on the process for preparing the crosslinked fine particles (C), and for example, an emulsion polymerization process is available. That is to say, the crosslinking monomer and other monomers are emulsified in water by the use of a surface active agent, and polymerization is conducted at 0 to 50° C. using a radical polymerization initiator such as a peroxide catalyst or a redox catalyst as a polymerization initiator, and if necessary, in the presence of a molecular weight modifier such as a mercaptan compound or a halogenated hydrocarbon. When the prescribed polymerization conversion is reached, a reaction terminator such as N,N-diethylhydroxylamine is added to terminate the polymerization reaction. Then, the unreacted monomers are removed from the polymerization system by means of steam distillation or the like. Thus, crosslinked fine particles can be synthesized.

There is no specific limitation on the surface active agent for use in the preparation of the crosslinked fine particles by emulsion polymerization. For example, any of an anionic surface active agent, a cationic surface active agent, a nonionic surface active agent, an ampholytic surface active agent and a reactive emulsifying agent can be used, or a mixture of plural surface active agents can be used. Examples of the anionic surface active agents include alkylnaphthalenesulfonate and alkylbenzenesulfonate. Examples of the cationic surface active agents include alkyl trimethylammonium salt and dialkyl dimethylammonium salt. Examples of the nonionic surface active agents include polyoxyethylene alkyl ether, polyoxyethylene alkylallyl ether, polyoxyethylene fatty acid ester, polyoxyethylene sorbitan fatty acid ester and fatty acid monoglyceride.

It is possible to prepare the crosslinked fine particles without using the crosslinking monomer.

Examples of such processes include:

a process wherein a peroxide or the like is added as a crosslinking agent to the latex particles to crosslink the latex particles,

a process wherein the polymerization conversion is increased to perform gelation inside the latex particles, and

a process wherein a crosslinking agent such as a metallic salt is added to perform crosslinking inside the particles utilizing a functional group such as a carboxyl group.

The latex containing the crosslinked fine particles obtained by the emulsion polymerization is solidified by salting out or the like, then washed and dried to obtain solid crosslinked fine particles.

For solidifying the crosslinked fine particles, a method other than the method of salting out is available. For example, when a nonionic surface active agent is used as the surface active agent, the system is heated to a temperature of not lower than the cloud point of the nonionic surface active agent, whereby the crosslinked fine particle component can be solidified. Also when a surface active agent other than the nonionic surface active agent is used for the polymerization, the nonionic surface active agent is added after the polymerization and the system is heated to a temperature of not lower than the cloud point, whereby the crosslinked fine particle component can be solidified.

In the present invention, crosslinked fine particles having a particle diameter of usually 30 to 500 nm, preferably 40 to 200 nm, are used. The method to control the diameter of the crosslinked fine particles is not specifically restricted. In the synthesis of the crosslinked fine particles by emulsion polymerization, however, a method of changing the amount of an emulsifying agent to control the number of micelles in the emulsion polymerization and thereby control the particle diameter is available.

In the resin composition of the invention, the crosslinked fine particles (C) are desirably contained in amounts of 1 to 50 parts by weight, preferably 5 to 30 parts by weight, based on 100 parts by weight of the phenolic resin (A). If the amounts of the crosslinked fine particles are less than 1 part by weight, thermal shock resistance of the resulting cured product is occasionally lowered. If the amount thereof exceeds 50 parts by weight, lowering of heat resistance or lowering of compatibility with other components takes place.

Since the crosslinked fine particles (C) have high compatibility with the component (A), modification with an epoxy compound or the like does not necessarily have to be carried out.

### (D) Photosensitive acid generator

The photosensitive acid generator (referred to as an “acid generator (D)” hereinafter) for use in the invention is a compound that generates an acid by irradiation with radiation or the like. Owing to the catalytic action of the thus generated acid, the alkyl ether group of the crosslinking agent (B) reacts with the phenolic resin (A) with dealcoholization to cure the composition, and therefore, when the photosensitive insulating resin composition of the invention is used, a negative pattern can be formed.

The acid generator (D) is not specifically restricted provided that it is a compound that generates an acid by the irradiation with radiation or the like. Examples of such compounds include an onium salt compound, a halogen-containing compound, a diazoketone compound, a sulfone compound, a sulfonic acid compound, a sulfonimide compound and a diazomethane compound. More specifically, there can be mentioned the following compounds.

Onium salt compound

Examples of the onium salt compounds include iodonium salt, sulfonium salt, phosphonium salt, diazonium salt and pyridinium salt.

Specific examples of preferred onium salts include diphenyliodonium trifluoromethanesulfonate, diphenyliodonium p-toluenesulfonate, diphenyliodonium hexafluoroantimonate, diphenyliodonium hexafluorophosphate, diphenyliodonium tetrafluoroborate, triphenylsulfonium trifluoromethanesulfonate, triphenylsulfonium p-toluenesulfonate, triphenylsulfonium hexafluoroantimonate, 4-t-butylphenyl•diphenylsulfonium trifluoromethanesulfonate, 4-t-butylphenyl•diphenylsulfonium p-toluenesulfonate and 4,7-di-n-butoxynaphthyltetrahydrothiophenium trifluoromethanesulfonate.

Halogen-containing compound

Examples of the halogen-containing compounds include haloalkyl group-containing hydrocarbon compounds and haloalkyl group-containing heterocyclic compounds.

Specific examples of preferred halogen-containing compounds include 1,10-bromo-n-decane, 1,1-bis(4-chlorophenyl)-2,2,2-trichloroethane, phenyl-bis(trichloromethyl)-s-triazine, 4-methoxyphenyl-bis(trichloromethyl)-s-triazine, styryl-bis(trichloromethyl)-s-triazine and naphthyl-bis(trichloromethyl)-s-triazine.

Diazoketone compound

Examples of the diazoketone compounds include a 1,3-diketo-2-diazo compound, a diazobenzoquinone compound and a diazonaphthoquinone compound. Specifically, there can be mentioned 1,2-naphthoquinonediazido-4-sulfonic acid ester compounds of phenols.

Sulfone compound

Examples of the sulfone compounds include a βketosulfone compound, a β-sulfonylsulfone compound and β-diazo compounds of these compounds. Specifically, there can be mentioned 4-trisphenacylsulfone, mesitylphenacylsulfone and bis(phenacylsulfonyl)methane.

Sulfonic acid compound

Examples of the sulfonic acid compounds include alkylsulfonic acid esters, haloalkylsulfonic acid esters, arylsulfonic acid esters and iminosulfonates. Specifically, there can be mentioned benzoin tosylate, pyrogallol tristrifluoromethanesulfonate, o-nitrobenzyl trifluoromethanesulfonate and o-nitrobenzyl p-toluenesulfonate.

Sulfonimide compound

Examples of the sulfonimide compounds include N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)bicyclo[2.2.1]hept-5-ene-2,3-dicarboxyimide and N-(trifluoromethylsulfonyloxy)naphthylimide.

Diazomethane compound

Examples of the diazomethane compounds include bis(trifluoromethylsulfonyl)diazomethane, bis(cyclohexylsulfonyl)diazomethane and bis(phenylsulfonyl)diazomethane.

In the present invention, the acid generators (D) mentioned above can be used singly or as a mixture of two or more kinds.

From the viewpoint of ensuring sensitivity, resolution and pattern shape of the resin composition of the invention, the amount of the acid generator (D) is in the range of 0.1 to 10 parts by weight, preferably 0.3 to 5 parts by weight, based on 100 parts by weight of the phenolic compound (A). If the amount of the acid generator (D) is less than 0.1 part by weight, curing becomes insufficient and heat resistance is lowered. If the amount thereof exceeds 10 parts by weight, transparency to the radiation is liable to be lowered to induce deterioration of the pattern shape.

In order to enhance the acid generation efficiency of the acid generator (D), various sensitizers may be added to the resin composition of the invention when needed.

### (E) Solvent

The organic solvent (E) is added for the purpose of improving handling properties of the resin composition and controlling viscosity or storage stability of the composition. The type of the organic solvent is not specifically restricted. Examples of the organic solvents include ethylene glycol monoalkyl ether acetates, such as ethylene glycol monomethyl ether acetate and ethylene glycol monoethyl ether acetate;

propylene glycol monoalkyl ethers, such as propylene glycol monomethyl ether, propylene glycol monoethyl ether, propylene glycol monopropyl ether and propylene glycol monobutyl ether; propylene glycol dialkyl ethers, such as propylene glycol dimethyl ether, propylene glycol diethyl ether, propylene glycol dipropyl ether and propylene glycol dibutyl ether;

propylene glycol monoalkyl ether acetates, such as propylene glycol monomethyl ether acetate, propylene glycol monoethyl ether acetate, propylene glycol monopropyl ether acetate and propylene glycol monobutyl ether acetate;

cellosoleves, such as ethyl cellosolve and butyl cellosolve;

carbitols, such as butyl carbitol;

lactic acid esters, such as methyl lactate, ethyl lactate, n-propyl lactate and isopropyl lactate;

aliphatic carboxylic acid esters, such as ethyl acetate, n-propyl acetate, isopropyl acetate, n-butyl acetate, isobutyl acetate, n-amyl acetate, isoamyl acetate, isopropyl propionate, n-butyl propionate and isobutyl propionate;

other esters, such as methyl 3-methoxypropionate, ethyl 3-methoxypropionate, methyl 3-ethoxypropionate, ethyl 3-ethoxypropionate, methyl pyruvate and ethyl pyruvate;

aromatic hydrocarbons, such as toluene and xylene; ketones, such as 2-heptanone, 3-heptanone, 4-heptanone and cyclohexanone;

amides, such as N-dimethylformamide, N-methylacetamide, N,N-dimethylacetamide and N-methylpyrrolidone;

and lactones, such as γ-butyrolactone. These organic solvents can be used singly or as a mixture of two or more kinds.

The amount of the solvent for use in the invention is properly selected according to the use of the composition and the coating method used, and there is no specific limitation on the amount of the solvent provided that a homogeneous composition can be obtained. The solvent is used in such an amount that the proportion of the solvent in the resulting liquid composition becomes usually 5 to 60% by weight, preferably 10 to 40% by weight.

### Other components (F)

To the photosensitive resin composition of the invention, an epoxy resin can be added as an additive (F). Examples of the epoxy resins include a phenolic navolak epoxy resin, a cresol novolak epoxy resin, a bisphenol epoxy resin, a trisphenol epoxy resin, a tetraphenol epoxy resin, a phenol-xylylene epoxy resin, a naphthol-xylylene epoxy resin, a phenol-naphthol epoxy resin, a phenol-dicyclopentadiene epoxy resin and an alicyclic epoxy resin. Further, an inorganic filler can be added, and examples of such fillers include silica, aluminum hydroxide and barium sulfate. Furthermore, other additives, such as high-molecular weight additive, reactive diluent, leveling agent, wettability improver, surface active agent, plasticizer, antioxidant, antistatic agent, mildew-proofing agent, moisture conditioner and flame retardant, can be added.

### Process for preparing the composition

The resin composition of the invention is prepared by dispersing and mixing the given amounts of the above components by the use of a dispersing machine such as a dissolver, a homogenizer or a three-roll mill. The above components may be filtered through a mesh membrane filter or the like, when needed.

The photosensitive insulating resin composition of the invention comprises the phenolic resin (A), the crosslinking agent (B), the crosslinked fine particles (C), the acid generator (D), the solvent (E), and if necessary, other additives (F), and the composition has excellent resolution. A cured product of the composition is excellent in electrical insulating properties, thermal shock resistance, heat resistance and chemical resistance.

Accordingly, the photosensitive insulating resin composition of the invention can be favorably used particularly as a solder resist of a multi-layer circuit board of a semiconductor device or as a material for forming fine wiring.

### Cured product

The cured product according to the invention is obtained by curing the above-mentioned photosensitive insulating resin composition.

The cured product of the invention is used as, for example, such a cured product as described below.

The photosensitive insulating resin composition of the invention is applied onto a copper-clad laminate or a substrate such as a silicon wafer or an alumina substrate provided with a copper sputter film and then dried to evaporate a solvent, whereby a coating film is formed. Thereafter, the coating film is exposed to radiation through a mask of desired pattern and then subjected to heat treatment (this heat treatment is referred to as “PEB” hereinafter) to promote the reaction of the phenolic resin with the crosslinking agent. Then, the film is developed with an alkaline developing solution to dissolve and remove the unexposed area, whereby a desired pattern can be obtained.

In order to allow the film to exhibit insulating properties, the film is wholly exposed to radiation after the development and then subjected to heat treatment to obtain a cured film.

Examples of the methods to apply the resin composition onto the substrate include dipping, spraying, bar coating, roll coating, spin coating, curtain coating, gravure printing, silk screening and ink jet method. The thickness of the coating film can be appropriately adjusted by controlling the coating means and the solid concentration or the viscosity of the composition solution.

Examples of the radiations used for the exposure include ultraviolet rays, electron rays and laser beam from radiation sources such as a low-pressure mercury lamp, a high-pressure mercury lamp, a metal halide lamp, a g-line stepper and an i-line stepper. The exposure light quantity is appropriately determined according to the radiation source used, the thickness of the composition film, etc. In case of irradiation with ultraviolet rays from a high-pressure mercury lamp, the exposure light quantity is in the range of about 1,000 to 20,000 J/m² for the film thickness of 10 to 50 μm.

After the exposure, PEB treatment is carried out in order to promote the curing reaction of the phenolic resin (A) with the crosslinking agent (B) due to the generated acid. Although the conditions of the PEB treatment vary depending upon the amount of the resin composition and the film thickness, the treatment is carried out at a temperature of usually 70 to 150° C., preferably 80 to 120° C., for a period of about 1 to 60 minutes.

Thereafter, the film is developed with an alkaline developing solution to dissolve and remove the unexposed area (resin composition having been not cured), whereby a pattern of desired shape is formed. Examples of the developing methods used herein include shower developing, spray developing, immersion developing and paddle developing. The development is carried out under the conditions of usually 20 to 40° C. and about 1 to 10 minutes.

The alkaline developing solution is, for example, an alkaline aqueous solution obtained by dissolving an alkaline compound, such as sodium hydroxide, potassium hydroxide, ammonia water, tetramethylammonium hydroxide or choline, in water so that the concentration becomes about 1 to 10% by weight. To the alkaline aqueous solution, a water-soluble organic solvent, such as methanol or ethanol, or a surface active agent can be added in an appropriate amount. After the development with the alkaline aqueous solution, the film is washed with water and dried.

In order to allow the film to sufficiently exhibit properties as an insulating film, the film is wholly exposed to radiation after the development and then subjected to heat treatment, whereby the film can be sufficiently cured. Although the curing conditions are not specifically restricted, they are determined according to the use of the cured product. For example, the film is irradiated with ultraviolet rays from a high-pressure mercury lamp to perform exposure of 10,000 to 50,000 J/m² and then heated at a temperature of 50 to 200° C. for a period of about 30 minutes to 10 hours, whereby the composition can be cured.

To promote the curing reaction sufficiently or to prevent deformation of the resulting pattern shape, heating can be carried out in two stages. For example, in the first stage, heating is carried out at a temperature of 50 to 100° C. for a period of about 10 minutes to 2 hours, and in the second stage, heating is carried out at a temperature of 80 to 200° C. for a period of about 30 minutes to 10 hours.

Under the above-mentioned curing conditions, a general oven, an infrared oven or the like can be used as the heating means.

### EFFECT OF THE INVENTION

Since the photosensitive insulating resin composition of the invention comprises the alkali-soluble resin (A) having a phenolic hydroxyl group, the compound (B) containing at least two alkyl-etherificated amino groups in the molecule, the crosslinked fine particles (C) and the photosensitive acid generator (D), the composition has excellent resolution and heat resistance, and besides, a cured product excellent in various properties such as resolution, electrical insulating properties, thermal shock resistance and chemical resistance can be obtained from the composition.

The photosensitive insulating resin composition has excellent resolution, and its cured product has excellent electrical insulating properties, thermal shock resistance, heat resistance and chemical resistance.

Accordingly, the photosensitive insulting resin composition of the invention can be favorably used particularly as a solder resist of a multi-layer circuit board of a semiconductor device or as a material for forming fine wiring.

### EXAMPLE

The present invention is further described with reference to the following examples, but it should be construed that the invention is in no way limited to those examples. The term “part(s)” used in the examples and the comparative examples means “part(s) by weight”, unless otherwise noted.

The properties of the cured product were measured in the following manner.

Resolution

A copper-clad laminate (substrate thickness: 0.6 mm, size: 10 cm square) having been subjected to surface roughening was coated with a photosensitive insulting resin composition and then heated at 90° C. for 10 minutes in a convection oven to form a coating film having a uniform thickness of 30 μm. Thereafter, using an aligner (MA-100 manufactured by Karl Suss Co.), the film was exposed to ultraviolet rays from a high-pressure mercury lamp through a pattern mask in such a manner that the exposure light quantity at a wavelength of 350 nm became 3,000 to 5,000 J/m². Then, the film was subjected PEB at 90° C. for 15 minutes in a convection oven and then subjected to shower developing (pressure: 3 kgf/cm²) at 30° C. for 3 minutes using a 1 wt % sodium hydroxide aqueous solution. The minimum size of the resulting pattern was taken as a resolution.

Electrical insulating properties (volume resistivity)

A SUS substrate was coated with a photosensitive insulting resin composition and then heated at 90° C. for 10 minutes in a convection oven to form a resin coating film having a uniform thickness of 30 μm. The film was exposed by the use of a high-pressure mercury lamp in such a manner that the exposure light quantity at a wavelength of 350 nm became 10,000 J/m². Thereafter, the film was heated at 150° C. for 2 hours and then at 170° C. for 2 hours in a convection oven to obtain a cured film. The cured film was subjected to a resistance property test under the conditions of a temperature of 85° C., a humidity of 85% and a period of 500 hours by the use of a constant-temperature constant-humidity test machine (manufactured by ESPEC Corp.) The volume resistivity between layers was measured before and after the test to examine the resistance properties.

Thermal shock resistance

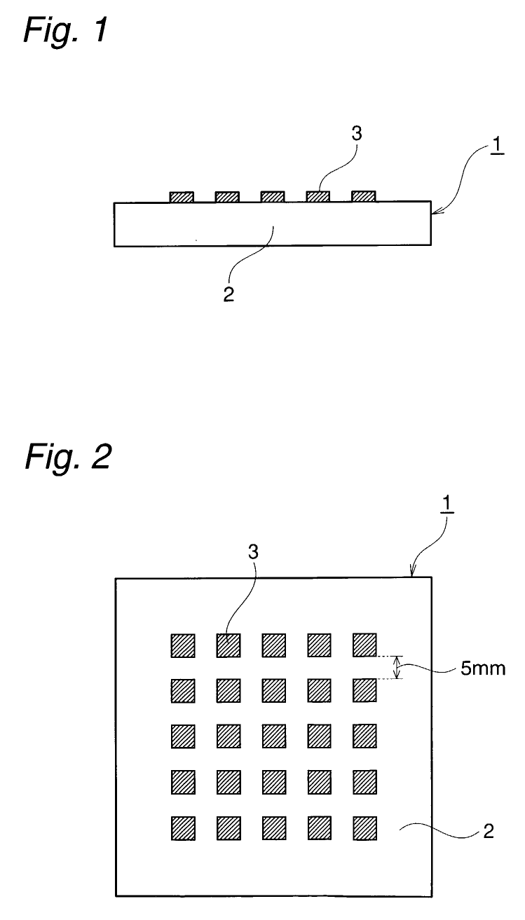

The board (copper-clad board) shown in FIG. 1 was coated with a resin composition and then heated at 90° C. for 10 minutes in a convection oven to form a resin coating film having a uniform thickness of 30 μm. Thereafter, the film was exposed to ultraviolet rays of 10,000 J/m² by the use of a high-pressure mercury lamp. The film was heated at 150° C. for 2 hours and then at 170° C. for 2 hours to obtain a cured film. The resulting board was subjected to a thermal shock resistance test (one cycle: −55° C./30min to 125° C./30 min) by the use of a thermal shock test machine (TSA-40L manufactured by ESPEC Corp.). The number of cycles at the end of which defects of the cured film such as crack had occurred was examined.

Heat resistance

A cured film of a resin composition was prepared, and a test specimen (3 mm×20 mm, thickness: 50 μm) of the cured film was measured on the glass transition temperature (Tg) by the DMA method under the conditions of a load of 3.0 g and a heating rate of 5.0° C./min. The glass transition temperature was regarded as an indication of the heat resistance. High Tg means good heat resistance.

Chemical resistance

A SUS substrate was coated with a photosensitive insulting resin composition and then heated at 90° C. for 10 minutes in a convection oven to form a resin coating film having a uniform thickness of 30 μm. The film was exposed by the use of a high-pressure mercury lamp in such a manner that the exposure light quantity at a wavelength of 350 nm became 10,000 J/M². Thereafter, the film was heated at 150° C. for 2 hours and then at 170° C. for 2 hours in a convection oven to obtain a cured film. The cured film was immersed in various chemicals (alkali, organic solvent) to examine chemical resistance of the film.

To examine the alkali resistance, the cured film was immersed in a 10 wt % sodium hydroxide aqueous solution (40° C.) for 30 minutes, and to examine the organic solvent resistance, the cured film was immersed in acetone (30° C.) for 30 minutes. In either case, the film was evaluated based on the following criteria.

AA: No change was observed.

BB: A part of the film surface was whitened.

CC: Peeling or film surface roughening was observed.

The components used in the examples and the comparative examples are as follows.

Phenolic resin

A-1: cresol novolak resin consisting of m-cresol/p-cresol (60/40, by mol) (weight-average molecular weight in terms of polystyrene: 8,700)

A-2: polyhydroxystyrene (available from Maruzen Oil Co., Ltd., trade name: MARUKA LYNCUR S-2P)

A-3: phenol-xylylene glycol condensation resin (Mitsui Chemicals, Inc., trade name: XLC-3L)

Phenolic compound

a-1: 1,1-bis(4-hydroxyphenyl)-1-[4-[1-(4-hydroxyphenyl)-1-methylethyl]phenyl]ethane

Crosslinking agent

B-1: hexamethoxymethyl melamine (Mitsui Sytec K.K., trade name: Cymel 300)

B-2: tetramethoxymethyl glycoluril (Mitsui Sytec K.K., trade name: Cymel 1174)

Crosslinked fine particles

C-1: fine particles of a copolymer of butadiene/hydroxybutyl methacrylate/methacrylic acid/divinylbenzene (67/25/6/2, by wt %), average particle diameter=60 mm

C-2: fine particles of a copolymer of butadiene/acrylonitrile/methacrylic acid/divinylbenzene (62/25/10/3, by wt %), average particle diameter=68 mm

Acid generator

D-1: styryl-bis(trichloromethyl)-s-triazine

D-2: 4,7-di-n-butoxynaphthyltetrahydrothiophenium trifluoromethanesulfonate

Solvent

E-1: ethyl lactate

E-2: 2-heptanone

Other additives

F-1: o-phenol novolak epoxy resin (Yuka Shell K.K., trade name: EP-152)

F-2: tetraphenol epoxy resin (Yuka Shell K.K., trade name: EP-1031S)

### EXAMPLE 1

100 Parts by weight of the phenolic resin (A-1), 30 parts by weight of the crosslinking agent (B-1), 10 parts by weight of the crosslinked fine particles (C-1) and 2 parts by weight of the acid generator (D-1) were mixed with 120 parts by weight of ethyl acetate (solvent, referred to as “E-1”) as shown in Table 1, to obtain a photosensitive insulating resin composition.

The properties of the composition were evaluated in accordance with the aforesaid evaluation methods.

The results are set forth in Table 2.

### EXAMPLES 2-6

Photosensitive insulating resin compositions of the formulations shown in Table 1 were prepared in the same manner as in Example 1.

The properties of the compositions were evaluated in the same manner as in Example 1.

The results are set forth in Table 2.

### Comparative Examples 1-4

Photosensitive insulating resin compositions shown in Table 1 were prepared in the same manner as in Example 1.

The properties of the compositions were evaluated in the same manner as in Example 1.

The results are set forth in Table 2.

TABLE 1
Formulation of the composition (part(s) by weight)

| | | | | | | | Cross | | | | | | |
|---|---|---|---|---|---|---|---|---|---|---|---|---|---|
| | | | | | Cross- | | linked | | | | | | |
| | Phenolic resin | | | | linking | | fine | | Acid | | | | |
| | Phenolic compound | | | | agent | | particles | | generator | | Solvent | | Additives |
| | A-1 | A-2 | A-3 | a-1 | B-1 | B-2 | C-1 | C-2 | D-1 | D-2 | S-1 | E-2 | F-1 |
| Ex. 1 | 80 | 20 | | | 30 | | 10 | | 2 | | 120 | | |
| Ex. 2 | 80 | | | 20 | 25 | | 15 | | 1 | | 100 | | 120 |
| Ex. 3 | 85 | 15 | | | | 20 | 10 | | 2 | | | 100 | |
| Ex. 4 | 80 | 10 | | 10 | 20 | | | | | 1 | 120 | | |
| Ex. 5 | 80 | | | 20 | | 25 | | | 1 | | 110 | | 120 |
| Ex. 6 | 70 | | 30 | | 30 | | 15 | | 1 | | | 100 | |
| Comp. | 80 | 20 | | | 30 | | | | 2 | | 120 | | |
| Ex. 1 | | | | | | | | | | | | | |
| Comp. | 80 | 20 | | | 30 | | | | 2 | | 120 | | 120 |
| Ex. 2 | | | | | | | | | | | | | |

Notes: To Comparative Examples 1 and 2, the crosslinked fine particles were not added.

TABLE 2
Evaluation results

| | | Electrical | | | | | |
|---|---|---|---|---|---|---|---|
| | | insulating | | | | | |
| | | properties | | | | | |
| | | Before | After | Thermal | | Chemical resistance | |
| | Reso- | the | the | shock | Heat | | Organic |
| | lution | test | test | resistance | resistance | Alkali | solvent |
| | (μm) | (Ω · cm) | (Ω · cm) | (cycles) | (° C.) | resistance | resistance |
| Ex. 1 | 20 | 3 × 10¹⁵ | 8 × 10¹⁴ | 900 | 210 | AA | AA |
| Ex. 2 | 25 | 5 × 10¹⁵ | 1 × 10¹⁵ | 1000 | 205 | AA | AA |
| Ex. 3 | 20 | 1 × 10¹⁵ | 7 × 10¹⁴ | 800 | 200 | AA | AA |
| Ex. 4 | 20 | 3 × 10¹⁵ | 8 × 10¹⁴ | 1000 | 215 | AA | AA |
| Ex. 5 | 30 | 2 × 10¹⁵ | 5 × 10¹⁴ | 900 | 195 | AA | AA |
| Ex. 6 | 20 | 5 × 10¹⁵ | 1 × 10¹⁵ | 1000 | 215 | AA | AA |
| Comp. | 20 | 5 × 10¹⁵ | 8 × 10¹⁴ | 150 | 210 | AA | AA |
| Ex. 1 | 4 | | | | | | |
| Comp. | 25 | 3 × 10¹⁵ | 5 × 10¹⁴ | 200 | 205 | AA | AA |
| Ex. 2 | | | | | | | |

What is claimed is:

1. A photosensitive insulating resin composition comprising (A) an alkali-soluble resin having a phenolic hydroxyl group, (B) a compound containing at least two alkyl-etherificated amino groups in the molecule, (C) crosslinked fine particles, (D) a photosensitive acid generator and (E) a solvent.

2. The photosensitive insulating resin composition as claimed in claim 1, wherein the compound (B), the crosslinked fine particles (C) and the photosensitive acid generator (D) are contained in amounts of 1 to 100 parts by weight, 1 to 50 parts by weight and 0.1 to 10 parts by weight, respectively, based on 100 parts by weight of the alkali-soluble resin (A).

3. A cured product obtained by curing the photosensitive insulating resin composition of claim 1 or 2.
